(19) United States
(12) Patent Application Publication
(10) Pub. No.: US 2013/0315782 A1
(43) Pub. Date: Nov. 28, 2013

(54) Biochip and fabrication thereof

(71) Applicant: JUNG-TANG HUANG, Taipei (TW)

(72) Inventor: JUNG-TANG HUANG, Taipei (TW)

(21) Appl. No.: 13/671,644

(22) Filed: Nov. 8, 2012

(30) Foreign Application Priority Data
Nov. 8, 2011 (TW) 100140675

(51) Int. Cl. G01N 27/00; H01L 23/31

(52) U.S. Cl. CPC G01N 27/00; H01L 23/31
USPC 422/69; 438/49

(57) ABSTRACT

A biochip comprising a plastic substrate, an IC chip, and a sealing cover is disclosed in this invention. The plastic substrate combines the function of sample inlet area, separating structure, micro-fluidic channel, flow resistor, detection area, and capillary pump or suction area. Sealing the plastic substrate with porous cover could make the structure of micro-fluidic to form the capillary effect or degas-driven effect, and drive the sample naturally without extra pump. The detection area is constituted by the IC chip which is embedded into the plastic substrate, and the IC chip includes the amplifier circuit and detection structure. In the detection area, there uses the biological specific conjugates to catch the bio-particles, nano-particles, or macromolecule sensitively. And finally, transfer the detected electric signal to a mobile communication device.

### FIELD OF INVENTION

The present invention is related to a biochip and its fabrication method. An IC chip embedded in the plastic substrate is formed by way of injection insert molding or hot embossing. The IC chip is for detecting nanoscale particles or biopolymer specimen electrically in the fluid sample with high specificity and sensitivity, The PDMS cover plate bonds with the plastic substrate through using vacuum packaging to form capillarity or degas status, which provide the driving force to drive the fluid flow in the microfluidic channel of the biochip.

### DESCRIPTION OF RELATED ART

The point-of-care diagnosis means a direct measurement in the patient's side, which features a disposable, low cost, simple to use, and just a small amount of sample for leading to available test results. In addition to using point-of-care diagnosis for clinical testing by the professionals at the hospital the patients or the general public can also use the point-of-care diagnosis in any non-hospital place. The device only needs a specimen to be inputted and the test results are quickly obtained, so this advantage is often referred to as a one-step assays or one-handling step assays. In the market common point of care diagnostic means used for the immunoassay is a technology commonly used in the detection of antigen. The simplest and commercial point of care detection is using the lateral flow assays. Lateral flow assays are low-cost, disposable, and only need tens of microliters of sample, the most common instance is a pregnancy testing. Its main limitation is a qualitative measurement; however, for many diagnoses quantitative measurement are often needed.

It is well known that the feature of the biochip is disposable, such as blood glucose test chip using electrochemical measurement; however, if the disease detection of the biochip is complex or need quantitative results, even microfluidic lab-on-chip devices, often need to employing fluorescence detection analysis. Fluorescence analyzer is a standard equipment of the medical institution; it is an expensive and large equipment which is not portable. Therefore in the present invention a biochip is developed by embedding a small detecting IC chip with a microfluidic plastic substrate, which not only reach the functionality of lab-on-chip devices, but also need a simple electrical signal reader such as smart mobile devices, and even more convenient, than blood glucose testing. However, seamless connection and the smooth flow between the detection area of the IC chip and microfluidic channel of plastic substrate is an issue not easy to overcome, the present invention is to provide an assembly structure and the way to solve the above problem.

### SUMMARY

Based on the above background, optical methods are often used in biological detection, for example, a fluorescent analyzer is needed to observe test results, but the fluorescence analyzer is a high cost instrument, it is difficult for the general public to have one in hand.

Accordingly, the purpose of the present invention is to develop a point of care detecting biochip without conducting fluorescence detection, but instead employing an IC chip with function of analysis and amplification of detected signal on an electrical detection platform. IC chip takes the advantages of easy to be mass-produced, cheap, small volume, and simple to detect signal. Therefore the present invention embeds this detection IC chip in a plastic substrate, and covers a polymer plate to form an innovative biochip. The plastic substrate has a variety of microfluidic structures: the inlet region of the specimen, the separation structure, microfluidic channel, the flow resistance, capillary pump or suction area. PDMS or soft polymer plate covering on the plastic substrates to seal microfluidic structures can form degas-driven or capillary-driven flow. The sample dropping into the inlet region is driven to flow through the separation structure, wherein micro-size particles such as blood cells are indwelled, while nanoscale particles or biopolymer sustained through a microfluidic channel into the detection area, eventually to the capillary pump or suction area. Capillary pump or suction area with the flow resistance in the middle of the flow channel can control the flow rate of the fluid; detection area by the IC chip embedded in the plastic substrate contains the detection elements, which use biological coupling modification specific to nano-particles or biopolymers in the specimen and via sensitive capture for converting into electrical signals. The golden fingers are set to the edge of the plastic substrate via a USB interface to connect a reader such as a smartphone, provide power to the IC chip, read the detection, signal after analog to digital conversion, and finally display detectable concentration on the reader to reach the point-of-care diagnosis. This biochip device can be mass-produced; the price is cheap, light and small volume, disposable, a small amount of sample, speed detection, the use of a simple operation. It also needs to be emphasized here is the present invention not just relies on capillarity or degas-driven flow to drive micro fluid; using the injection pump with outside power source is also a viable option.

### BRIEF DESCRIPTION OF DRAWINGS

The detailed drawings of this invention will be fully understood from the following descriptions wherein:

FIG. 1 shows a schematic drawing of the plastic substrate by injection insert molding or hot embossing.

FIG 2 shows a schematic drawing of IC chip produced by MEMS, CMOS-MEMS, or CMOS NEMS fabrication process.

FIG. 3A shows a schematic drawing of the sealing cover for sealing the plastic substrate; FIG. 3B shows the bottom side of the sealing cover with microfluidic channel.

FIG. 4A provides a schematic 3-D view of assembling PDMS cap with the substrate containing micro fluidic structures; FIG. 4B shows the assembled biochip.

FIG. 5 illustrates a mobile communication device combined with a signal processing device as a reader for displaying the detected signal from the biochip of the present invention.

FIG. 6 provides a schematic drawing of the chip of embodiment 1.

FIG. 7 provides a schematic drawing of the chip of embodiment 2.

FIG. 8 provides a schematic drawing of the chip of embodiment 3

The following description should be read with reference to the drawings, in which like elements in different drawings are numbered in like fashion. The drawings, which are not necessarily to scale, depict selected embodiments and are not intended to limit the scope of the invention. Although examples of construction, dimensions, and materials are illustrated for the various elements, those skilled in the art will recognize that many of the examples provided have suitable alternatives that may be utilized.

### DETAILED DESCRIPTION

For the convenience of the following description, to define some terms first: Fluid sample is a body fluid, including blood cerebrospinal fluid, gastric juice, and a variety of digestive juices, semen, saliva, tears, sweat, urine, vaginal, fluids etc., or a solution containing the specimen. The plastic substrate is a substrate made of polymethylmethacrylate (PMMA), polyethylene terephthalate (PETE), polycarbonate, and Polydimethylsiloxane (PDMS) or a biocompatible polymer material. Nano sensing material can be nanowires (nanowire) used for sensing, for example, carbon nanotubes, silicon nanowire, InP nanowire, GaN nanowire or semiconductor materials, or nanometer semiconductor film, for example, the graphene.

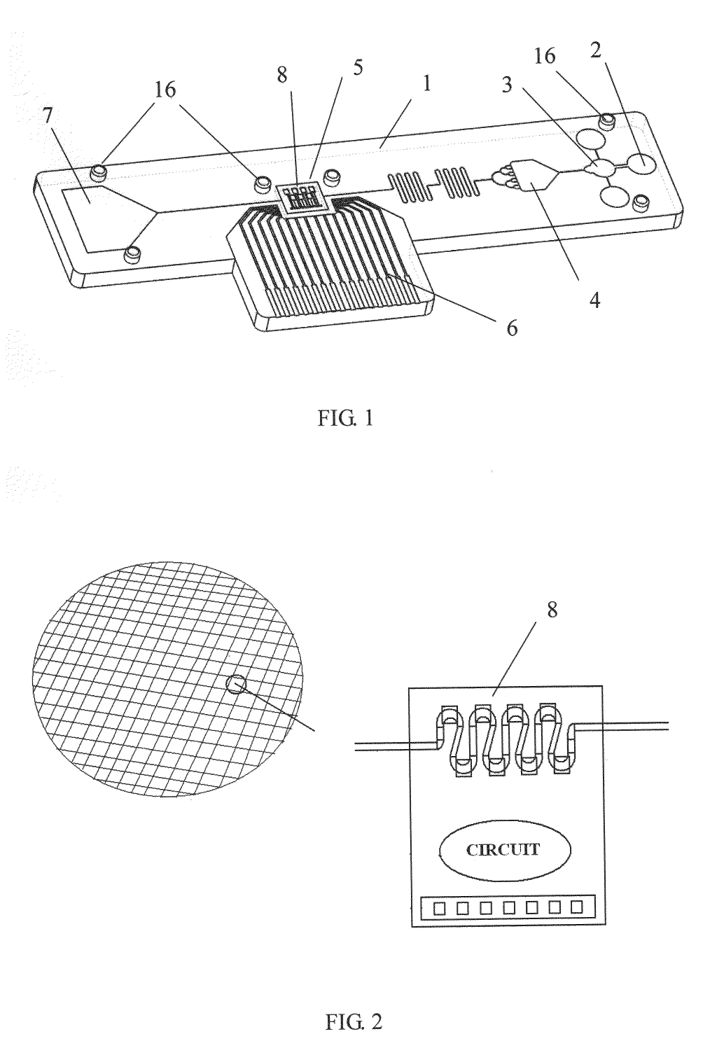

As shown in FIG. 1, a plastic substrate 1, having a variety of microfluidic structures, including at least the inlet region 2 of the fluid sample, a separation structure 3, a purification or mixer structure 4, a detection zone groove 5, a capillary pomp or suction area 7, outlet, etc. therebetween are connected by microfluidic channels. On the plastic substrate, it can achieve separation, purification, capillary drive purposes; further at the edge of the plastic substrate golden fingers 6 are set and extended with convergent spacing to the edge of the detection zone groove 5. Note that the separation structure 3 may be capable to retain blood cells in the cavity and let the remaining plasma pass to the mixer structure 4.

At least one integrated circuit (IC) chip 8 is embedded in the detection zone groove of the plastic substrate. The IC chip has at least one detection structure, which is modified by using biological conjugates. Each detection structure can measure nanoscale particles or biopolymers in the specimen with high specificity and sensitivity. The I/O pads of the IC chip are wire bonded to the corresponding golden fingers or parallel conductor traces on the edge of the plastic substrate detection zone groove to obtain the external power source and output a detection signal to the outside;

A sealing cover made of a biocompatible polymer material such as Polydimethylsiloxane (POMS) or porous polymer is used to seal the plastic substrate embedded with the IC chip, the bottom side of the sealing cover thereof corresponding to the test structure of the IC chip has a microfluidic channel, which is leakage-free connected to input/output port of the microfluidic channel on the plastic substrate. The specimen in the tubular micro channel can move by degas-driven flow or capillary flow through test structures at the IC chip without leakage. The top side of the sealing cover might be deposited with a layer of airtight polymer or materials which would enhance the reliability of the degas-driven flow.

FIG. 2 illustrates the IC chip 8 which contains several biological sensing elements. The sensing mechanism is selected from resistive, capacitive, or transistors-based sensor. Carbon nanotubes or graphenes or other nano material are working as nano sensing material, which are functionalized by specific biopolymers. The biopolymers particularly refer to antibodies or aptamers, or carbohydrates. The sensing element may be a plurality or array-type, to provide the quantitative testing of a variety of target biomarkers of the subject's body. The manufacturing method is divided into two portions, the first portion is to produce an array of carbon nanotube field-effect transistor (CNTFET) or other types of sensors with nano sensing material; the second portion is using sophisticated dispenser to functionalize nano sensing material with specific biological polymer. The IC chip may further contain the signal processing and amplification circuit fabricated by the use of CMOS process or CMOS-MEMS process or CMOS-NEMS process. IC chip with amplifier may detect very low electrical signal generated by the rare amount of the target polymer, for example 1 pg/ml concentration target polymer corresponding electrical signals only at current level of pA. For case of measured electrical current above nA, the IC chip may not need to include signal processing and amplification circuit and could be fabricated by using only the process of micro-electromechanical (MEMS).

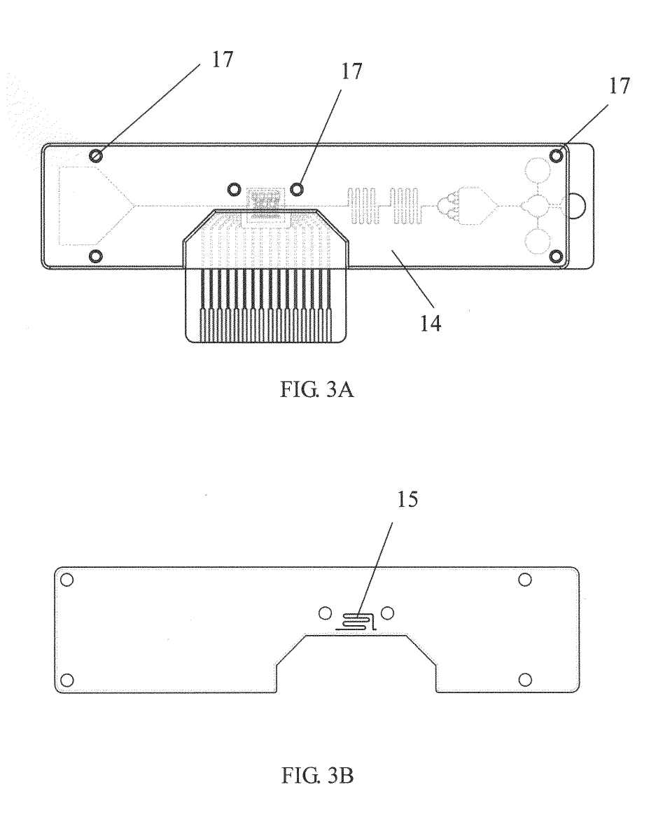

FIG. 3 shows the sealing cover 14, made of Polydimethylsiloxane (PDMS) or porous polymer and used to seal the plastic substrate embedded with IC chip. The bottom side of the sealing cover 14 thereof corresponding to the test structures of the IC chip has a microfluidic channel 15, which is leakage-free connecting with input/output port of the microfluidic channel on the plastic substrate. The specimen in the tubular microfluidic channel can move by degas-driven flow or capillary flow through test structures at the IC chip without leakage. The sealing cover needs to open area over pads on the IC chip for wire bonding. The wire bonding is to connect between golden fingers on the plastic substrate and the IC chip pads. The manufacture method of the sealing cover 14 is silicone injection molding, or silicone transfer molding technology. Note that after molding, the top side of the sealing cover might be deposited with a layer of airtight polymer or material, which would enhance the reliability of the degas-driven flow.

The assembly procedure of the biochip in the present invention is described as following:

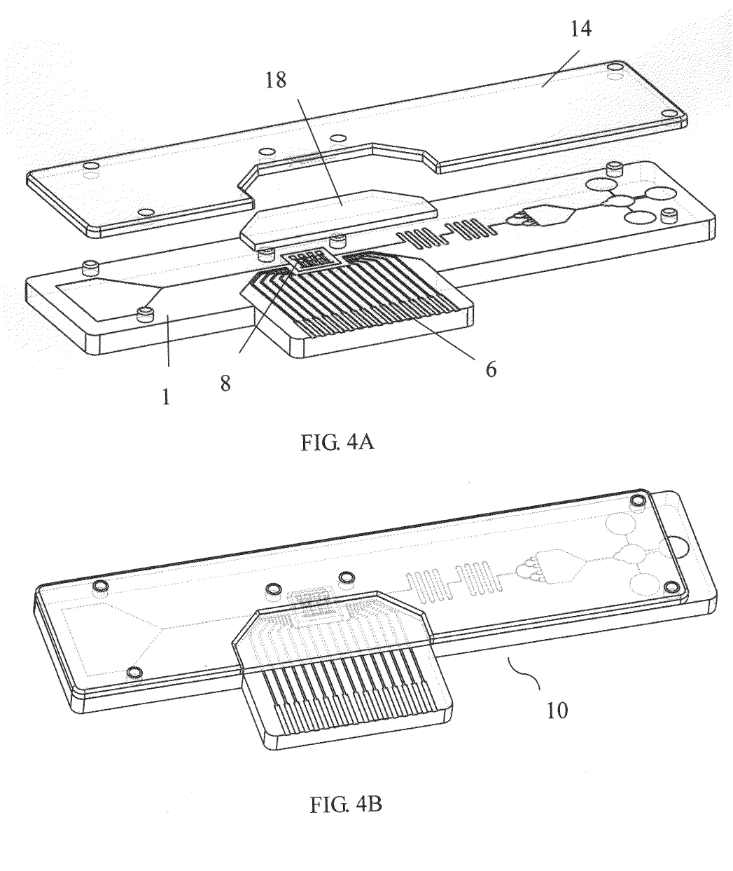

Step 1, as shown in FIG 4A, by using vertical injection molding machine, the IC chip is directly placed to the insert mold assembly where the rectangular space surrounded by four locating pins in the lower mold, by letting the detection area of embedded IC chip be faced downward. The mold cavity formed by the upper mold and the lower mold is the plastic substrate 1. After injection, then cooled, and ejected, it can yield the plastic substrate embedded IC chip containing a variety of microfluidic structures. Note that the IC chip used in this step has already contained nano sensing material deposited on the test structures, e.g. CNTFETs array.

Step 2, as shown in FIG. 4A, clean the injection-molded microfluidic channel on the plastic substrate and modify the surface of the overall plastic substrate into hydrophilic condition. The modification methods may be the use of oxygen plasma with Tetraethylorthosilicate (TEOS) immersion. In addition, the PDMS sealing cover 14 is also subjected to surface treatment.

Step 3, as shown in FIG 4A, following embedded IC chip in Step 2 a precision dispenser dispatches and immobilizes the functionalized biopolymer onto nano-sensing materials.

Step 4, cover and bond the PDMS sealing cover 14 with the plastic substrate 1 by the aid of alignment holes 17 (FIG. 3) on the sealing cover 14 and the alignment pins 16 (FIG. 1) on the plastic substrate 1 as shown in FIG. 4A. Note that the PDMS sealing cover 14 may fully lay over the microfluidic structures of the plastic substrate 1 to form an enclosed microfluidic space except the inlet.

Step 5, the IC chip is wire bonded to the plastic substrate, and then dispensed with glue 18 to protect the bonding wires. The complete assembly of the biochip 10 is shown in FIG. 4B.

Step 6, the assembled biochip is loaded into a vacuum bag for further vacuum packaging.

The present invention intends to provide point of care diagnosis for users without expertise of professional medical inspectors. Therefore each sample volume offered by the user may not be precise, which may require biochips with automatic quantitative metering ability. Due to the closed outlet of microfluidic channel on the biochip of the present invention, microfluidic internal volume is fixed, for example, a preferred embodiment is 3-4 microliters (μL). As most people directly puncture finger prick blood roughly 5 microliters, and then drop into the biochip as the biological sample, eventually only 3 microliters, for instance, can be precisely metered into detection zone. Even the sample is other body fluids such as urine, as long as it is added dropwise to the inlet of the biochip more than 3 microliters, 3 microliters would be the basis for calculating accurate concentration, especially for point of care diagnostic biochips,

Referring to FIG. 5, the reader tor catching the detected signal from the biochip comprises a microcontroller (μC), analog-to-digital converter (ADC), display monitors, a power supply (battery), such as a notebook computer or mobile phone. Through the USB interface a connector to the golden fingers on the edges of the plastic substrate of the biochip can provide power to the IC chip and read the detection signal. After analog to digital conversion, the digitized signal could be displayed as the detected concentration in the reader, and achieve the point-of-care diagnosis.

If the IC chip only retains biological sensing without signal amplification circuit, the reader for the biochip 10 could be separated into two parts: one is a mobile communication device 30; the other is a signal processing device 31 connected to the golden fingers set on the edges of the plastic substrate of the biochip. The signal processing device 31 includes a multiplexer, a current amplifier, a microcontroller (μC), power supply (battery), further adding a wireless communication module, such as Bluetooth low-power module. The signals of sensing elements on the biochip 10 are scanned and amplified, and transmitted through the wireless communication module to mobile phone or other mobile communications device.

The preferred procedure for using the biochip of the present invention is described below. The user first uses a smartphone camera to shoot identification barcode affixed outside of the biochip vacuum packaging or uses a near-field communication (NFC) reader, which may be a standard function of the smartphone, to read the attached RFID tags or input identification code on the phone screen through the APP program. Next, tear vacuum packaging to remove the present invented biochip, and in 3-5 minutes drop the sample into inlet of the biochip. The specimen is driven under negative pressure flow into the separation structure, purification or mixed structure, the IC chip, capillary pump or suction area. After waiting about 10 minutes, the user can read the data. The result is corresponding to whether is positive or negative reaction, as well as its concentration. The data can also be uploaded to the cloud for subsequent processing by the medical staff to do further diagnosis.

### Embodiment 1

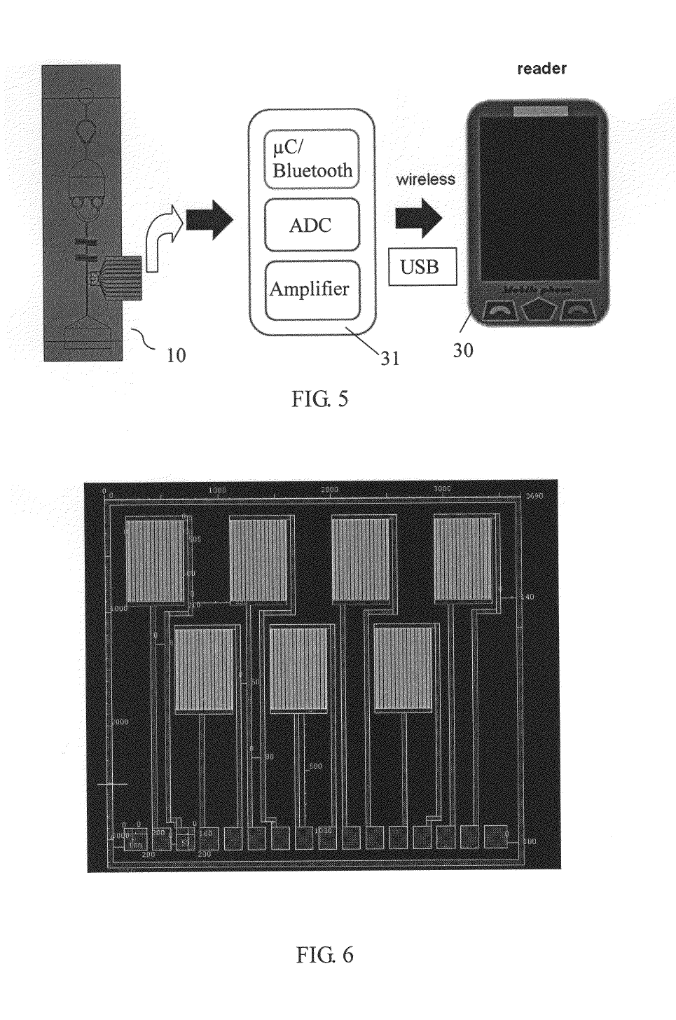

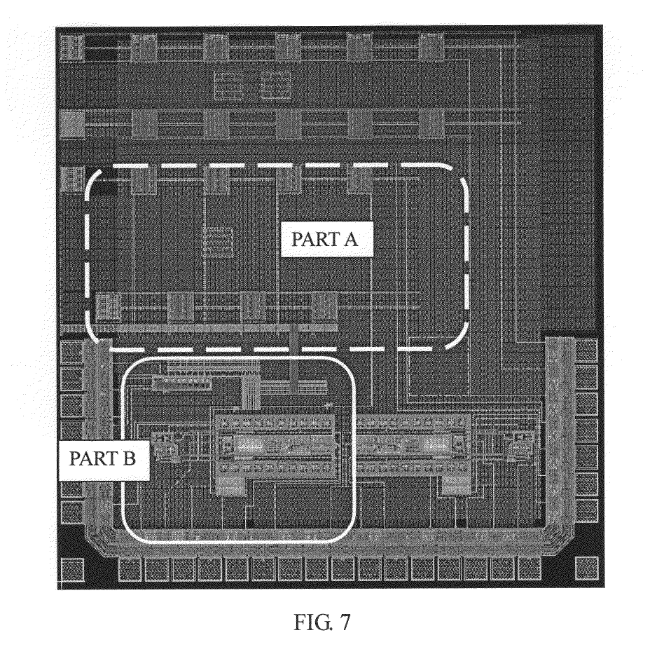

FIG. 6 shows an embodiment of the IC chip with chip size of 4 * 4 (mm²), There is no amplifier or circuit in this IC chip, but main sensing structure composed of seven comb-shaped electrode elements, one of them as the control electrode of the circuit, while the remaining six comb electrode components were given different analytes-specific aptamers modified carbon nanotuhes. The target analytes may be six different cancer biomarkers in the serum or plasma. For wire bonding the pads with I/O ports of the plastic substrate 1, the entire pad layout is on the same side. With the subsequent plastic microfluidic channel packaging, a set of real-time sensing biochip may detect six kinds of different analytes.

### Embodiment 2

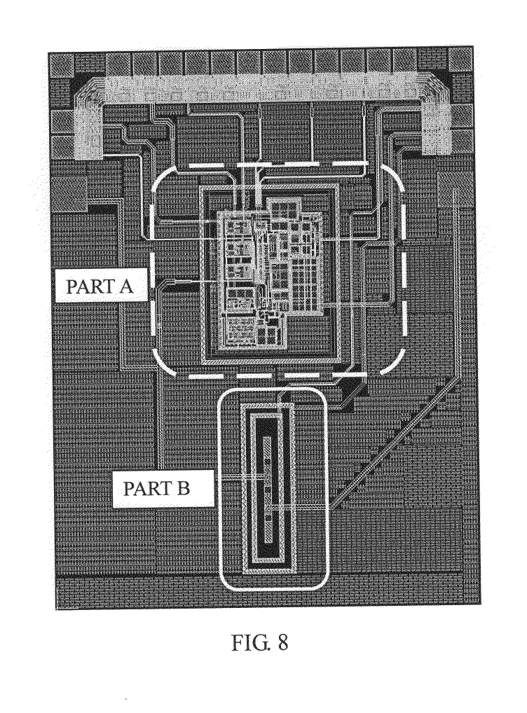

FIG. 7 shows another embodiment of the IC chip with chip size of 2.23884*2.28145 (mm²). Part A is a signal processing circuit connected to CNTFETs sensing element through a multiplexer to select different sensing element output. The signal processing circuit mainly comprises a clock generator, a chopper, and switched capacitor circuit. Part B is the sensing structure composing of nine comb-shaped electrode elements, one of them as the control electrode of the circuit, while the remaining eight comb-electrode components were given different analyte-specific aptamers modified carbon nanotubes. For wire bonding the pads with I/O ports of the plastic substrate 1, the entire pad layout is on the same side. With the subsequent plastic microfluidic channel packaging, a set of real-time sensing biochip may detect eight kinds of different analytes.

### Embodiment 3

FIG. 8 illustrates another embodiment of the IC chip with chip size of 2.364 * 1.794 (mm²). Part A shows the amplifier circuit capable of measuring nA to μA current changes, which mainly use the charge integrator for amplifying the input current signal into a voltage output. This area also contains three sets of operational amplifiers, switches, oscillators, and a multiplexer. The entire pads are on the same side, in order to facilitate follow-up integration with the plastic substrate 1. Part B is the counting structural elements, having a pore with the size of 30 microns, for counting the number of cancer cells in size of 15 to 25 microns. Since the height of the pore and micro fluidlc channel is around 30 microns, it needs an electroforming process to fabricate the thick metal seeding from the PAD layer of the IC chip.

In this embodiments the PDMS plate would not cover the outlet of microfluidic channel, but let micro fluid flow through the outlet and fully count all the cancer cells in the sample.

Having thus described the several embodiments of the present invention, those of skill in the art will readily appreciate that other embodiments may be made and used which fall within the scope of the claims attached hereto. Numerous advantages of the invention covered by this document have been set forth in the foregoing description. It will be understood that this disclosure is, in many respects, only illustrative. Changes may be made in details, particularly in matters of shape, size and arrangement of parts without exceeding the scope of the invention.

What is claimed is:

1. A biochip, comprising:
a plastic substrate, having a variety of microfluidic structures, including at least a inlet region of the fluid sample, a separation structure, a mixer structure, a detection zone groove, a capillary pump or suction area, outlet, therebetween are connected by microfluidic channels; further at the edge of the plastic substrate golden fingers are set and extended with convergent spacing to the edge of the detection zone groove;
at least one integrated circuit (IC) chip is embedded in the detection zone groove of the plastic substrate, the IC chip has at least one detection structure, which is modified by using biological conjugates; each detection structure measures nanoscale particles or biopolymers in the fluid sample with high specificity and sensitivity; the I/O pads of the IC chip are wire bonded to the corresponding golden fingers on the edge of the plastic substrate detection zone groove to obtain the external power source and output a detection signal to the outside;
a sealing cover made of Polydimethyisiloxane (PDMS) or porous polymer is used to seal the plastic substrate embedded with the IC chip into the biochip, the bottom side of the sealing cover thereof corresponding to the test structure of the IC chip has a microfluidic channel, which is leakage-free connected to input/output port of the microfluidic channel on the plastic substrate;
the fluid sample in the tubular microfluidic channel of the biochip moves by degas-driven flow or capillary flow through test structures at the IC chip without leakage.

2. The biochip according claim 1 wherein the nano sensing material is selected from the group consists of carbon nanotubes, silicon nanowire, InP nanowire, GaN nanowire or semiconductor nanowire, graphene or nanometer semiconductor film.

3. The biochip according claim 1 wherein the defection structure is based on electrical sensing mechanism selected from the group consists of resistor-type, capacitor-type, or transistor-type.

4. The biochip according claim 1 wherein the biological conjugates are selected from the group consists of antibodies, aptamers, carbohydrates, and their combinations,

5. The biochip according claim 1 wherein the fluid sample is body fluid, selected from the group consist of blood, cerebrospinal fluid, gastric juice, a variety of digestive juices, semen, saliva, tears, sweat, urine, vaginal fluids, or a solution containing the specimen.

6. The biochip according claim 1 wherein the top sides of the sealing cover is further deposited with a layer of airtight polymer or material, which enhances the reliability of the degas-driven flow.

7. The biochip according claim 1 wherein, a reader is further added for catching the detected signal from the biochip, the reader is separated into two part: one is a mobile communication device; the other is a signal processing device connected to the golden fingers on the edges of the plastic substrate of the biochip; the signal processing device comprising a microcontroller (μC), analog-to-digital converter (ADC); through a USB interface the mobile communication device provides power to the signal processing device and the IC chip and read the detection signal; after analog to digital conversion, the digitized signal is displayed as the detected concentration in the mobile communication device, and achieve the point-of-care diagnosis.

8. The biochip according claim 1 wherein a reader is further added for catching the detected signal from the biochip; the reader is separated into two parts: one is a mobile communication device; the other is a signal processing device connected to the golden fingers on the edges of the plastic substrate of the biochip; the signal processing device includes a multiplexer, a current amplifier, a microcontroller (μC), power supply (battery), further adding a wireless communication module; the signals of sensing elements on the biochip are scanned and amplified, and transmitted through the wireless communication module to the mobile communications device.

9. A method for fabricating a biochip consisting of a plastic substrate, an IC chip, and a sealing cover, comprising;
step 1, the IC chip is directly embedded into the plastic substrate with the insert mold injection method by letting the detection area of embedded IC chip be faced downward; the plastic substrate containing a variety of microfluidic structures; the IC chip before inserting has already contained nano-sensing materials deposited on its detection structures;
step 2, clean the injection-molded microfluidic channel on the plastic substrate and modify the surface of the overall plastic substrate into hydrophilic condition;
step 3, following embedded IC chip in step 2 a precision dispenser dispatches and immobilizes biological conjugates onto nano-sensing materials;
step 4, cover and bond the sealing cover with the plastic substrate by the aid of alignment holes on the sealing cover and the alignment pins on the plastic substrate;
step 5, the IC chip is wire bonded, to the plastic substrate and then dispensed with glue to protect the bonding wires, which completes fabrication of the biochip;
step 6, the fabricated biochip is loaded into a vacuum bag for further vacuum packaging.

10. The method according claim 9 wherein the nano-sensing material is selected from the group consists of carbon nanotubes, silicon nanowire, InP nanowire, GaN nanowire or semiconductor nanowire, graphene or nanometer semiconductor film.

11. The fabrication method according claim 9 wherein the detection structure is based on electrical sensing mechanism selected from the group consists of resistor-type. capacitor-type, or transistor-type.

12. The method according claim 9 wherein the biological conjugates are selected from the group consists of antibodies, aptamers, carbohydrates, and their combinations.

13. The method according claim 9 wherein the sealing cover is made of Polydimethylsiloxane (PDMS) or porous polymer.
